(19) United States
(12) Patent Application Publication
(10) Pub. No.: US 2022/0187603 A1
(43) Pub. Date: Jun. 16, 2022

(54) AN OPTICAL SYSTEM

(71) Applicant: 3M INNOVATIVE PROPERTIES COMPANY, St. Paul, MN (US)

(72) Inventors: Yi hang LV, Shanghai (CN); Zhisheng Yun, Sammamish, WA (US); Timothy L. Wong, St. Paul, MN (US); Susan L. Kent, Shorewood, MN (US); Erin A. McDowell, Afton, MN (US)

(21) Appl. No.: 17/441,538

(22) PCT Filed: Apr. 10, 2019
(86) PCT No.: PCT/CN2019/082050

§ 371 Date: Sep. 21, 2021

(51) Int. Cl. G02B 27/01; G02F 1/13363; G02F 1/13; G02B 5/30; H01L 51/52

(52) U.S. Cl. CPC G02B 27/0172; G02F 1/133638; G02F 1/1313; G02B 2027/0178; G02B 5/3041; H01L 51/52; G02B 5/3058

(57) ABSTRACT

An optical system (200) provides wide field of view in a compact system having a low profile. The optical system (200) includes a display (10), a reflective polarizer (60), a minor (100), and a partial reflector (110), to provide a folded optical path between an image source and an eye of a viewer (30).

### TECHNICAL FIELD

The disclosure generally relates to optical systems and particularly to folded optics.

### BACKGROUND

Optical systems capable of forming images from illuminated objects find numerous and important applications. The optical system may include a display and various optical components between the display and an eye of the viewer in an optical path. It is advantageous for such systems to be compact in size, have a wide field of view and high contrast and be viewable in all ambient lighting conditions. Folding of the optical path results in a compact optical system that is demanded in applications limited by space. Such optical systems may be included in head-mounted displays, such as virtual reality displays, to provide images to a viewer.

### SUMMARY

Various aspects and embodiments described herein relate to an optical system having folded optical path.

In some aspects of the present description, an optical system includes a display adapted to emit an image for viewing by a viewer. The emitted image includes a central image ray propagating along a folded optical axis between the display and the viewer. The optical system includes a reflective polarizer. The central image ray is incident on the reflective polarizer at a first incident angle between about 30 degrees to about 60 degrees, for each of at least one wavelength λ_{b} in a blue wavelength range and at least one wavelength λ_{g} in a green wavelength range and at least one wavelength λᵣ in a red wavelength range. The reflective polarizer transmits at least 70% of the incident central image ray having a first polarization state and reflects at least 70% of the incident central image ray having an orthogonal second polarization state. Further, for each of at least one wavelength λ_{bg} between λ_{b} and λ_{g} and at least one wavelength λ_{gr} between λ_{g} and λᵣ, the reflective polarizer transmits at least 70% of the incident central image ray having each of the first and second polarization states. The optical system further includes a mirror, the minor and the display being disposed on opposite sides of the reflective polarizer. The central image ray is substantially normally incident on the mirror, such that for at least λ_{b}, λ_{g}, and λᵣ, the minor reflects at least 70% of the incident central image ray for each of the first and second polarization states. The optical system further includes a partial reflector, the partial reflector and the viewer being disposed on opposite sides of the reflective polarizer. The central image ray is substantially normally incident on the partial reflector, such that for at least λ_{b}, λ_{g}, and λᵣ and for each of the first and second polarization states, the partial reflector reflects, and transmits, at least 30% of the incident central image ray.

These and other aspects of the present application will be apparent from the detailed description below. In no event, however, should the above summaries be construed as limitations on the claimed subject matter, which subject matter is defined solely by the attached claims.

### BRIEF DESCRIPTION OF DRAWINGS

The various aspects of the disclosure will be discussed in greater detail with reference to the accompanying figures where,

FIG. 1 is a schematic diagram of a folded optical system according to an embodiment;

FIG. 2 is a schematic plot of transmittance versus wavelength.

The figures are not necessarily to scale. Like numbers used in the figures refer to like components. However, it will be understood that the use of a number to refer to a component in a given figure is not intended to limit the component in another figure labelled with the same number.

### DETAILED DESCRIPTION OF ILLUSTRATIVE EMBODIMENTS

Optical systems of the present description may be used in devices such as head-mounted displays to provide an efficient and wide field of view in a compact system having a low profile. In some embodiments, the optical system includes a display, a reflective polarizer, a mirror, and a partial reflector, to provide a folded optical path between an image source and an eye of a viewer.

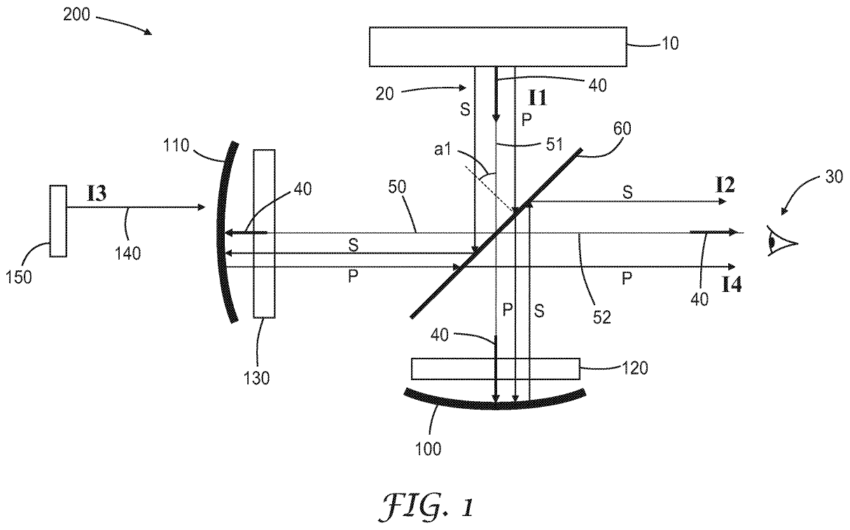

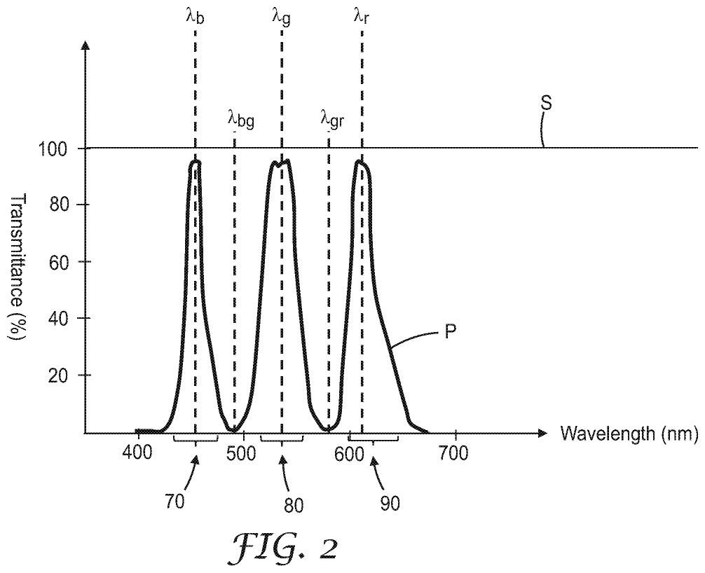

As shown schematically in FIGS. 1 and 2, the display (10) of an optical system (200) is adapted to emit an image (20) for viewing by a viewer (30). The viewer wears glasses and sees the image formed by the glasses and can also see the ambient image outside the glasses. The emitted image (20) has a central image ray (40) propagating along a folded optical axis (50) between the display and the viewer (30). The display may include one or more LEDs, including in some cases one or more laser diodes. Several such LEDs can be combined to produce a desired spectral distribution of light. The display may have red, green, and blue sub-elements to provide a full color image. For example, the outputs of red, green, and blue-emitting LEDs may be combined to provide nominally white light, or white-emitting LEDs may be used instead or additionally. The display 10 may be any suitable type of display including, for example, liquid crystal displays (LCDs) and organic light emitting diode (OLED) displays. The display 10 may be substantially flat or planar, or may be curved, or may include a plurality of flat or planar panels disposed at obtuse angles relative to one another. In certain aspects, the image emitted by the display may be substantially unpolarized.

The optical system further includes a reflective polarizer, wherein the central image ray (40) is incident on the reflective polarizer (60) at a first incident angle (a1) between about 15 degrees to about 75 degrees. In some embodiments, the first incident angle (a1) may be between about 30 degrees to about 60 degrees. The reflective polarizer (60) may be a wide-band reflective polarizer or a notch reflective polarizer. In some embodiments, the reflective polarizer (60) may be or include an absorbing linear polarizer, a multilayer polymeric reflective polarizer, or a laminate of a reflective polarizer and an absorbing linear polarizer, which substantially transmits light having a first polarization state (P) and substantially reflects light having an orthogonal second polarization state (S), causing the light emitted by the display (10) to be polarized. In certain embodiments, the reflective polarizer (60) may be a wire grid polarizer. In other embodiments, the reflective polarizer (60) may be a multilayer optical film polarizer. According to an embodiment, for each of at least one wavelength λ_{b} in a blue wavelength range (70) and at least one wavelength λ_{g} in a green wavelength range (80) and at least one wavelength λᵣ in a red wavelength range (90), the reflective polarizer (60) transmits at least 70% of the incident central image ray (40) having a first polarization state (P) and reflects at least 70% of the incident central image ray (40) having an orthogonal second polarization state (S). In certain aspects, the reflective polarizer (60) transmits at least 70-80%, or 75-85% of the incident central image ray (40) having a first polarization state (P) and reflects at least 70-80%, or 75-80% of the incident central image ray (40) having an orthogonal second polarization state (S).

For each of at least one wavelength λ_{bg} between λ_{b} and λ_{g} and at least one wavelength λ_{gr} between λ_{g} and λᵣ, the reflective polarizer transmits at least 70%, or between 70-80%, or between 75-85% of the incident central image ray (40) having each of the first polarization state (P) and second polarization state (S).

The optical system (200) further includes a mirror (100), wherein the mirror and the display (10) are disposed on opposite sides of the reflective polarizer (60). In some aspects, the mirror (100) may be a broadband dielectric mirror having high reflectance for a wide spectrum of wavelengths, with high degrees of surface flatness, low scattering, and applicable over wide angles of incidence, as described elsewhere. The central image ray (40) is substantially normally incident on the mirror (100), such that for at least one wavelength λ_{b} in the blue wavelength range (70), and at least one wavelength λ_{g} in the green wavelength range (80), and at least one wavelength λᵣ in the red wavelength range (90), the mirror (100) reflects at least 70%, or between 70-80%, or between 75-85% of the incident central image ray (40) for each of the first polarization state (P) and second polarization state (S).

The optical system (200) further includes a partial reflector (110), wherein the partial reflector and the viewer (30) are disposed on opposite sides of the reflective polarizer (60). The partial reflector (110) may have an average optical reflectance of at least 25%, or at least 30%, or at least 30-40%, or in some embodiments at least 40-50%, for at least one desired or predetermined wavelength and may have an average optical transmission of at least 30% for the at least one desired or predetermined wavelength. The at least one desired or predetermined wavelength may be a desired or predetermined plurality of wavelengths which may be a single continuous range of wavelengths (e.g., a visible range of 400 nm to 700 nm) or it may be a plurality of continuous ranges of wavelengths. According to certain embodiments, the blue wavelength range may be from about 425 nm to about 475 nm, the green wavelength range may be from about 525 nm to about 575 nm and the red wavelength range may be from about 625 nm to about 675 nm.

In some aspects, the partial reflector may be a notch reflector and the at least one desired or predetermined wavelength may include one or more wavelength ranges at least some of which having a full-width at half-maximum reflection band of no more than 100 nm or no more than 50 nm, for example. In other aspects, the partial reflector may be a 50/50 beam splitter obtained by evaporating metals, for instance, aluminum or silver, onto plastic or glass plates. According to an aspect of the disclosure, the partial reflector (110) transmits light (140) emitted by an ambient image (150). The viewer (30) is configured to receive and view the light (140) from ambient image (150) that is transmitted by the partial reflector (110).

According to an embodiment, the central image ray (40) is substantially normally incident on the partial reflector (110), such that for at least one wavelength λ_{b} in the blue wavelength range (70), and at least one wavelength λ_{g} in the green wavelength range (80), and at least one wavelength λᵣ in the red wavelength range (90), and for each of the first polarization state (P) and second polarization state (S), the partial reflector (110) reflects, and transmits, at least 30%, or at least about 30 to about 50% of the incident central image ray (40).

The folded optical axis (50) includes at least a first portion (51) and a second portion (52). In some embodiments, the first portion (51) of the folded optical axis (50) is orthogonal to the second portion (52) of the folded optical axis (50).

The optical system (200) includes a first retarder layer (120) disposed between the minor (100) and the reflective polarizer (60) to change the polarization of, for example, linearly polarized light emitted by the display (10) to, for example, rotationally polarized (circularly or elliptically polarized) light. In some embodiments, the first retarder layer (120) may be substantially a quarter wave retarder layer. In certain embodiments, the first retarder layer (120) may be a film laminated on the reflective polarizer (60) or may be a coating applied to the reflective polarizer (60). For example, the first retarder (120) may be an oriented polymer film laminated to the reflective polarizer (60), or a liquid crystal polymer coating on the reflective polarizer (60). Suitable coatings for forming a quarter wave retarder include, but not restricted to, linear photopolymerizable polymer (LPP) materials and liquid crystal polymer (LCP) materials, as described elsewhere. The first retarder (120) included in the optical system (200) may be a quarter wave retarder at at least one wavelength in the at least one desired wavelength. In some embodiments, the at least one desired wavelength is a desired plurality of wavelengths and the first retarder layer (120) is a quarter wave retarder at at least one wavelength in the desired plurality of wavelengths.

The optical system (200) further includes a second retarder layer (130) disposed between the partial reflector (110) and the reflective polarizer (60). In some embodiments, the second retarder layer (130) may be substantially a quarter wave retarder layer. In some aspects, the partial reflector (110) and the second quarter wave retarder (130) may be prepared, for instance, by coating a quarter wave retarder onto a partial reflector film, or by coating a partial reflector coating onto a quarter wave retarder film, or by laminating a partial reflector film and a quarter wave retarder film together. The second retarder (130) included in the optical system (200) may be a quarter wave retarder at at least one wavelength in the at least one desired wavelength. In some embodiments, the at least one desired wavelength is a desired plurality of wavelengths and the second retarder layer (130) is a quarter wave retarder at at least one wavelength in the desired plurality of wavelengths.

In some aspects, the image emitted by the display (10) has a first intensity (I1). The image transmitted by the optical system and viewed by the viewer (30) has a second intensity (I2). The image emitted by the display (10) reduces in intensity as it passes through the reflective polarizer (60), which substantially transmits light having a first polarization state (P). The light with first polarization state (P) passes through the first retarder (120) and a substantial portion of said light is reflected by the mirror (100) and passes through the first retarder (120) that converts the first polarization state (P) into a second polarization state (S). At least 70% of the incident central image ray (40) with the second polarization state (S) is reflected by the reflective polarizer (60) and reaches the viewer (30) with the second intensity (I2). In some embodiments, a ratio of the second intensity to the first intensity may be at least 0.5, or at least 0.6, or at least 0.7 or between 0.6-0.75. The second polarization state (S) of the central image ray (40) emitted by the display (10) that is incident on and reflected by the reflective polarizer (60) is partially reflected by the partial reflector (110) through the second wave retarder (130) that converts the second polarization state (S) into a first polarization state (P). At least 70% of the incident central image ray with the first polarization state (P) emitted by the second retarder (130) is transmitted by the reflective polarizer (60) and reaches the viewer (30).

In some aspects, the ambient image (150) has a third intensity (I3). The ambient image (150) transmitted by the optical system and viewed by the viewer (30) has a fourth intensity (I4). The third intensity (I3) of the ambient image reduces after the light (140) emitted by the image (150) passes through the partial reflector (110) and further reduces in intensity as it is transmitted by the reflective polarizer (60), which substantially transmits light having a first polarization state (P), before it reaches the viewer (30). In some embodiments, a ratio of the fourth intensity to the third intensity may be at least 0.15, or at least 0.20, or at least about 0.20 to 0.30.

The following is a list of exemplary embodiments:
Embodiment 1. An optical system including: a display adapted to emit an image for viewing by a viewer, the emitted image having a central image ray propagating along a folded optical axis between the display and the viewer; a reflective polarizer, the central image ray incident on the reflective polarizer at a first incident angle between about 30 degrees to about 60 degrees, for each of at least one wavelength λ_{b} in a blue wavelength range and at least one wavelength λ_{g} in a green wavelength range and at least one wavelength λᵣ in a red wavelength range, the reflective polarizer transmits at least 70% of the incident central image ray having a first polarization state and reflects at least 70% of the incident central image ray having an orthogonal second polarization state, and for each of at least one wavelength λ_{bg} between λ_{b} and λ_{g} and at least one wavelength λ_{gr} between λ_{g} and λᵣ, the reflective polarizer transmits at least 70% of the incident central image ray having each of the first and second polarization states; a mirror, the mirror and the display disposed on opposite sides of the reflective polarizer, the central image ray substantially normally incident on the mirror, such that for at least λ_{b}, λ_{g}, and λᵣ, the mirror reflects at least 70% of the incident central image ray for each of the first and second polarization states; and a partial reflector, the partial reflector and the viewer disposed on opposite sides of the reflective polarizer, the central image ray substantially normally incident on the partial reflector, such that for at least λ_{b}, λ_{g}, and λᵣ and for each of the first and second polarization states, the partial reflector reflects, and transmits, at least 30% of the incident central image ray.
Embodiment 2: The optical system of embodiment 1, wherein at least a first portion of the folded optical axis is orthogonal to at least a second portion of the folded optical axis.
Embodiment 3. The optical system of embodiment 1, wherein the blue wavelength range is from about 425 nm to about 475 nm.
Embodiment 4. The optical system of embodiment 1, wherein the green wavelength range is from about 525 nm to about 575 nm.
Embodiment 5. The optical system of embodiment 1, wherein the red wavelength range is from about 625 nm to about 675 nm.
Embodiment 6. The optical system of embodiment 1 further including a first retarder layer disposed between the mirror and the reflective polarizer, and a second retarder layer disposed between the partial reflector and the reflective polarizer.
Embodiment 7. The optical system of embodiment 6, wherein each of the first and second retarder layers is substantially a quarter wave retarder layer.
Embodiment 8. The optical system of embodiment 1,wherein the display is an organic light emitting display (OLED).
Embodiment 9. The optical system of embodiment 1, wherein the display is a liquid crystal display (LCD).
Embodiment 10. The optical system of embodiment 1, wherein the reflective polarizer is a wire grid polarizer.
Embodiment 11. The optical system of embodiment 1, wherein the reflective polarizer is a multilayer optical film polarizer.
Embodiment 12. The optical system of embodiment 1, wherein the viewer is configured to receive and view light from an ambient image and transmitted by the partial reflector.
Embodiment 13. The optical system of embodiment 1, wherein the ambient image has a third intensity, wherein the ambient image transmitted by the optical system and viewed by the viewer has a fourth intensity, a ratio of the fourth intensity to the third intensity being at least 0.15.
Embodiment 14. The optical system of embodiment 13, wherein the ratio of the fourth intensity to the third intensity is at least 0.2.
Embodiment 15. The optical system of embodiment 1, wherein the image emitted by the display is substantially unpolarized.
Embodiment 16. The optical system of embodiment 1, wherein the image emitted by the display has a first intensity, wherein the image transmitted by the optical system and viewed by the viewer has a second intensity, a ratio of the second intensity to the first intensity being at least 0.6.
Embodiment 17. The optical system of embodiment 16, wherein the ratio of the second intensity to the first intensity is at least 0.7.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific Embodiments shown and described without departing from the scope of the present disclosure. This application is intended to cover any adaptations or variations of the specific Embodiments discussed herein. Therefore, it is intended that this disclosure be limited only by the claims and the equivalents thereof.

1. An optical system comprising:
a display adapted to emit an image for viewing by a viewer, the emitted image comprising a central image ray propagating along a folded optical axis between the display and the viewer;
a reflective polarizer, the central image ray incident on the reflective polarizer at a first incident angle between about 30 degrees to about 60 degrees, for each of at least one wavelength λ_{b} in a blue wavelength range and at least one wavelength λ_{g} in a green wavelength range and at least one wavelength λᵣ in a red wavelength range, the reflective polarizer transmits at least 70% of the incident central image ray having a first polarization state and reflects at least 70% of the incident central image ray having an orthogonal second polarization state, and for each of at least one wavelength λ_{bg} between λ_{b} and λ_{g} and at least one wavelength λ_{gr} between λ_{g} and λᵣ, the reflective polarizer transmits at least 70% of the incident central image ray having each of the first and second polarization states;
a mirror, the minor and the display disposed on opposite sides of the reflective polarizer, the central image ray substantially normally incident on the minor, such that for at least λ_{b}, λ_{g}, and λᵣ, the minor reflects at least 70% of the incident central image ray for each of the first and second polarization states; and
a partial reflector, the partial reflector and the viewer disposed on opposite sides of the reflective polarizer, the central image ray substantially normally incident on the partial reflector, such that for at least λ_{b}, λ_{g}, and λᵣ and for each of the first and second polarization states, the partial reflector reflects, and transmits, at least 30% of the incident central image ray.

2. The optical system of claim 1, wherein at least a first portion of the folded optical axis is orthogonal to at least a second portion of the folded optical axis.

3. The optical system of claim 1, wherein the blue wavelength range is from about 425 nm to about 475 nm, the green wavelength range is from about 525 nm to about 575 nm, and the red wavelength range is from about 625 nm to about 675 nm.

4. The optical system of claim 1 further comprising a first retarder layer disposed between the minor and the reflective polarizer, and a second retarder layer disposed between the partial reflector and the reflective polarizer.

5. The optical system of claim 4, wherein each of the first and second retarder layers is substantially a quarter wave retarder layer.

6. The optical system of claim 1, wherein the display is an organic light emitting display (OLED).

7. The optical system of claim 1, wherein the display is a liquid crystal display (LCD).

8. The optical system of claim 1, wherein the reflective polarizer is a wire grid polarizer.

9. The optical system of claim 1, wherein the reflective polarizer is a multilayer optical film polarizer.

10. The optical system of claim 1, wherein the viewer is configured to receive and view light from an ambient image and transmitted by the partial reflector.

11. The optical system of claim 1, wherein the ambient image has a third intensity, wherein the ambient image transmitted by the optical system and viewed by the viewer has a fourth intensity, a ratio of the fourth intensity to the third intensity being at least 0.15.

12. The optical system of claim 11, wherein the ratio of the fourth intensity to the third intensity is at least 0.2.

13. The optical system of claim 1, wherein the image emitted by the display is substantially unpolarized.

14. The optical system of claim 1, wherein the image emitted by the display has a first intensity, wherein the image transmitted by the optical system and viewed by the viewer has a second intensity, a ratio of the second intensity to the first intensity being at least 0.6.

15. The optical system of claim 14, wherein the ratio of the second intensity to the first intensity is at least 0.7.
